(19) United States
(12) Patent Application Publication
(10) Pub. No.: US 2005/0000429 A1
(43) Pub. Date: Jan. 6, 2005

(54) Spiral gas flow plasma reactor

(75) Inventors: Wolfgang Neuberger, F.T. Labuan (MY); Alexei Solomatine, Bonn (DE)

Correspondence Address: BOLESH J. SKUTNIK PhD,JD, 515 Shaker Road, East Longmeadow, MA, 01028, US

(73) Assignee: CeramOptec Industries, Inc.

(21) Appl. No.: 10/847,012

(22) Filed: May 17, 2004

Related U.S. Application Data
(63) Continuation of application No. 09/950,337, filed on Sep. 11, 2001, now abandoned.

(51) Int. Cl. C23C 16/00

(52) U.S. Cl. 118/715; 118/728

(57) ABSTRACT

A plasma reactor and accompanying method for thin film deposition is disclosed, comprising a system of input means and exhaust means that produce an adjustable spiral flow of precursor gas used in creating a spatially stable plasma over large substrate surface areas. The flow of gas created by this configuration of input and exhaust means results in a plasma that remains uniform as it extends radially from the center to the edges of the substrate and is capable of high quality depositions and high deposition rates. In a preferred embodiment, the input means is in the form of a ring jet with a tangential flow component surrounding the substrate. Gas exhausts through exhaust means located at a preselected distance above the substrate. In a preferred embodiment, gas exhausts through a central exhaust aperture and a number of surrounding apertures located at a preselected distance from the central exhaust aperture. Both the central and surrounding exhaust apertures may be connected by an adjustable manifold to allow for coordinated positioning of the central and surrounding apertures. Additionally, apertures located at the bottom of the cavity can be used to input additional precursor gas so as to maintain the spiral flow over the substrate.

### REFERENCE TO RELATED CASE

This application is a continuation of co-pending U.S. patent application Ser. No. 09/950,337 filed on Sep. 11, 2001 by Wolfgang Neuberger and Alexei Solomatine, inventors, entitled “Spiral Gas Flow Plasma Reactor”, and incorporated by reference herein.

### BACKGROUND OF THE INVENTION

1. Field of the Invention

The invention concerns plasma reactors for use in commercial processes of film deposition, etching and other processing of large surfaces of a substrate.

2. Information Disclosure Statement

Plasmas are useful in many processes, including surface processing and film deposition. Plasma Enhanced Chemical Vapor Deposition (PECVD) is a useful and effective method for thin film deposition. Radio Frequency PECVD, in which radio frequency energy between 3 and 30 MHz is used to strike the plasma, is useful for deposition of silicon-based films. Microwave assisted PECVD of diamond and diamond-like films offers the ability to produce uniform films over larger substrate areas than hot filament CVD. Microwave assisted PECVD is also more suitable than hot filament CVD for high purity applications. Microwave plasma discharge is best achieved when using precursor gas in low pressure environments (less than 100 mm of Hg), as only then is it possible to carry out a homogeneous discharge having a volume sufficient for processing substrates of a significant size.

Non-plasma assisted methods have been disclosed that attempt to improve thin film deposition. For example, U.S. Pat. No. 5,672,204 (Habuka) describes an apparatus for vapor-phase epitaxial growth of thin films that allows a thin film to be formed on a substrate with a uniform thickness. This apparatus includes a flat cylindrical reaction vessel, supply nozzles for feeding a source gas from a peripheral part of the reaction vessel toward the center of the substrate, a gas outlet located above and over the center of the substrate, and heating means to affect growth of the thin film. Gas is introduced peripherally to create a horizontal rotary flow in the reaction vessel.

It is claimed that the disclosed apparatus has the ability to create uniform thin films on a substrate, but does not provide a uniform density of reaction/deposition gas over the substrate. The apparatus does not describe use in plasma assisted deposition, for which a uniform distribution of gas over a substrate is important for controlling power density and ensuring a uniform deposition. In this patent, gas introduced to the periphery of the reaction vessel becomes pulled toward the central exhaust aperture, both horizontally and vertically. Thus, a shape that is at least partially conical is formed, wherein gas toward the center of the substrate is higher than gas in the periphery, due both to the central exhaust and a buoyant force due to heating. Also, because all of the gas migrates to a single exhaust point, the concentration of carrier gas is higher towards the center. As described in col. 3, line 25, the concentration of source gas decreases from the periphery toward the center as source gas is consumed for epitaxial growth as it flows toward the center. However, because the flow rate increases toward the center, it is claimed that the distribution of deposited material can be made uniform. Although the final result is claimed to be a uniform growth of the thin film, it cannot be said that this configuration produces a homogeneous distribution of gas over the substrate, which would be important for plasma enhanced deposition processes, where deposition occurs substantially simultaneously over the entire substrate.

U.S. Pat. No. 6,179,924 (Zhao et al) discloses a simplified heater design for deposition of thin films, comprising a processing chamber, a metal pedestal for holding and heating a substrate, and a purge gas channel system disposed in the metal pedestal for preventing deposition on unwanted surfaces particularly around the periphery of the substrate and pedestal. The system is concerned with using purge gas to restrict the size of a deposition area and prevent unwanted deposition, rather than controlling the path of reactive gas.

The purge gas system includes an inlet feeding to multiple radial purge gas channels radiating from the central purge gas inlet out toward a perimeter of the metal pedestal, and an annular purge gas channel formed in the metal pedestal at the perimeter. In a specific embodiment, the annular purge gas channel is coupled to the surface via multiple nozzles arranged circularly near the perimeter to provide a purge guide ring integral to the metal pedestal. The purge gas system reduces the chance that the deposition and carrier gases (applied from above the substrate) will reach the edge and backside surfaces and deposit deposition gas on those unwanted surfaces. The purge gas system is purely to prevent undesired deposition and has no role in actual deposition; it does not input or control deposition and carrier gases beyond preventing deposition on the periphery of the substrate.

The purge gas channels input purge gas in a direction having a vertical component and a radial component (toward the center of the substrate). There is no component of the inputted gas flow that extends in the direction of the perimeter of the substrate or is in the same plane as the surface of the substrate. Therefore, because the input nozzles are angled toward the center of the substrate and not along the circumference, there is no ability to create a circular or spiral flow of any gas, whether it is deposition gas, carrier gas or purge gas.

U.S. Pat. No. 5,122,394 (Lindner) discloses a coating applicator for chemical-vapor deposition of films on glass surfaces or other substrates. The applicator includes a pair of opposing coating nozzles for applying a deposition and carrier gas to the substrate at such a concentration and velocity that coating of the surface is achieved under substantially reaction-rate-controlled conditions. Each coating nozzle is positioned adjacent the substrate with a small clearance between the nozzle and substrate; the clearance and the deposition area are open to the outside atmosphere. The opposing coating nozzles are directed toward each other at a selected angle with respect to the surface of the substrate. Inputted gas travels from the coating nozzles to a central recirculation duct. The angle and the clearance provide a condition where there is substantially no intermixing of coating vapors with the outside atmosphere. Additional external exhaust nozzles may be included, to remove spent coating material or to emit a barrier gas.

Apart from varying the velocity of the gas and the angle of the input nozzles, there is no description of any manipulation or alteration of the flow of input gas to create a certain distribution, including a spiral flow, over a substrate. This patent is concerned with directing nozzles at an angle towards the substrate to achieve a reduction of outside gas mixing with reaction gas, generally because this device is for use with a moving substrate where a sealed chamber would not be possible. There is no indication that a spiral flow apparatus would have any use or could be achieved with this invention. Also, external exhaust nozzles may exhaust at a rate relative to the recirculation duct, but cannot be coordinated in such a way as to affect the path or shape of the gas flow.

The above examples do not utilize plasma systems for deposition, and thus do not benefit from the advantages of incorporating plasmas in chemical vapor deposition. Although PECVD presents a significant improvement over conventional CVD systems, present plasma reactors suffer from a number of significant problems. Present plasma reactors require that the chamber be relatively small, requiring complex cooling systems. Also, the resultant plasmas are often uneven due to difficulty in maintaining a uniform density in a plasma as it extends from the center of the substrate, and thus cause uneven deposition rates and thicknesses on the substrate. These configurations often require the use of a rotating substrate or some other compensatory configuration to improve the consistency of the deposition. Present radio frequency plasma reactors, because of lower frequencies and size, often are of a density insufficient for current processing requirements.

One attempt to alleviate these problems is described by Besen et. al. (U.S. Pat. No. 5,501,740). In this invention, microwave energy is introduced into a chamber via dielectric windows, and a plasma is formed in the cavity for deposition. The dielectric windows are positioned under the substrate holder, and the microwave energy passes through the substrate holder from a coaxial cable positioned under the substrate holder, forming a plasma above the substrate. This configuration helps protect the dielectric windows from damage due to plasma deposition, but restricts the plasma size and the resulting potential substrate size. The distance between the surface of the substrate and the top of the reactor cavity can not exceed a length equal to half of the wavelength of a microwave, in order to produce a standing wave to increase the electric field strength in the area of plasma. The microwave will penetrate into a plasma, which extends above the full distance between the substrate and the top of the cavity and quickly fades as the body of the plasma extends beyond the substrate. Therefore, the size of a processable substrate is limited, and it usually does not exceed an area with a diameter of 100 mm.

In another device described in German Patent DE 19802971A1, the distance between the surface of the substrate and the top of the reactor cavity is not limited. Microwave energy passes over the substrate through a dielectric window ring symmetric to a central axis of the cylindrical cavity running parallel to the cavity walls. This configuration is potentially useful for protecting the dielectric window and for allowing deposition on larger substrates. Microwaves are introduced and enter the cavity in an axially symmetric fashion. Because the microwave does not pass through the substrate to reach the plasma zone, the distance between the holder and the top of the cavity need not be limited, and the maximum allowable substrate size is larger than what is possible in the Besen configuration. Precursor gas enters the cavity through an aperture located on the bottom of the cylindrical cavity, and exhausts through an aperture also located on the bottom of the cavity but positioned 180° from the input aperture in relation to the central axis of the cylindrical cavity. The plasma under action of Archimedes' force emerges above the surface of the substrate and loses strength and corresponding deposition rate as it leaves the substrate. This configuration can create more than one area of maximum electric field intensity in the space above a substrate. This results in a plasma of non-uniform density and deposition rates in the area above the substrate. The direction of the flow of gas over and around the substrate is dictated solely by the pressure differential created by exhausting gas. This configuration limits control of the gas flow to modifications in the volume of gas inputted or exhausted, leaving the operator little ability to change or limit the path of the gas flow to affect the uniformity and thickness of the deposition.

Another attempt at creating large size homogeneous thin films, by Blinov et. al., U.S. Pat. No. 5,643,365, was created for the purpose of creating large, rectangular shaped diamond or diamond-like films. In that application, an extended linear plasma in close proximity to the substrate is created with a plasma torch. According to the patent, homogeneous depositions of diamond or diamond-like films can be produced on large, rectangular shaped flat surfaces by scanning the substrate along the plasma torch, or alternatively, scanning the plasma torch along the substrate. Potential problems still exist with this application due to the complexity of the configuration of the apparatus and the substrate, and can result in potential inconsistencies in deposition thickness. Another problem with this apparatus is that it may only be suitable for flat rectangular surfaces.

Blinov et al. discussed other previous attempts at plasma reactors in U.S. Pat. No. 5,643,365, describing the prior applications and the problems inherent in each previous invention. Specifically, one application (U.S. Pat. No. 5,360,485) consists of a cone-shaped plasma that is useful for uniform coating of a large number of small surface areas. Its primary deficiency is its inability to uniformly coat large flat substrates.

Other applications discussed by Blinov et. al. deal with the creation of a ball plasma for use in deposition. The physical geometry of such ball plasmas results in a decrease in electric field intensity and resulting deposition thickness with increasing distance from the substrate center. Thus, these applications also suffer from the inability to create uniform deposition over large substrate areas.

Therefore, a need exists to provide a method for depositing homogeneous films, such as diamond and diamond-like films, on large (diameters greater than 100 mm) substrates, with consistent thicknesses at varying radial distances from the center of the substrate. The present invention satisfies this need.

### OBJECTS AND BRIEF SUMMARY OF THE INVENTION

It is an object of the present invention to provide a method that corrects the deficiencies of the known methods.

It is a further object of this invention to provide a device that corrects the deficiencies of the known devices.

It is another object of this invention to provide a method capable of producing a spiral flow of precursor gas that results in a particularly stable plasma, resulting in a homogeneous deposition of a desired thickness over a large substrate surface area.

It is yet another object of this invention to provide a device capable of producing a spiral flow of precursor gas that results in a particularly stable plasma, resulting in a homogeneous deposition of a desired thickness over a large substrate surface area.

Briefly stated, the present invention provides a plasma reactor for thin film deposition and an accompanying method. The reactor comprises a system of input means and exhaust means that produce an adjustable spiral flow of precursor gas used in creating a spatially stable plasma over large substrate surface areas. The flow of gas created by this configuration of input and exhaust means results in a plasma that remains uniform as it extends radially from the center to the edges of the substrate and is capable of high quality depositions and high deposition rates. In a preferred embodiment, the input means is in the form of a ring jet with a tangential flow component surrounding the substrate. Gas exhausts through exhaust means located at a preselected distance above the substrate. In a preferred embodiment, gas exhausts through a central exhaust aperture and a number of surrounding apertures located at a preselected distance from the central exhaust aperture. Both the central and surrounding exhaust apertures may be connected by an adjustable manifold to allow for coordinated positioning of the central and surrounding apertures. Additionally, apertures located at the bottom of the cavity can be used to input additional precursor gas so as to maintain the spiral flow over the substrate.

The above, and other objects, features and advantages of the present invention will become apparent from the following description read in conjunction with the accompanying drawings (in which like reference numbers in different drawings designate the same elements).

### BRIEF DESCRIPTION OF FIGURES

FIG. 1—Schematic of a cross sectional view of a preferred embodiment of the proposed invention in an illustrative configuration.

FIG. 2—Three-dimensional view of cavity interior represented in FIG. 1, including the spiral flow of precursor gas.

FIG. 3—Schematic as in FIG. 1, depicting the location of the planes perpendicular to the central axis depicted in FIGS. 4, 5 and 6.

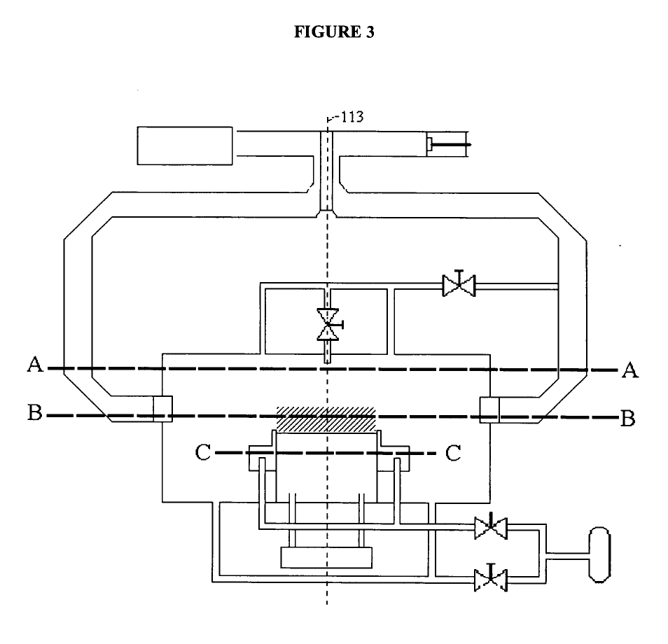

FIG. 4—A cross-sectional view of the embodiment represented in FIG. 1, in a plane perpendicular to the central vertical axis of the embodiment, at a point along line A-A.

FIG. 5—A cross-sectional view of the embodiment represented in FIG. 1, in a plane perpendicular to the central vertical axis of the embodiment, at a point along line B-B.

FIG. 6—A cross-sectional view of the embodiment represented in FIG. 1, in a plane perpendicular to the central vertical axis of the embodiment, at a point along line C-C.

### DETAILED DESCRIPTION OF PREFERRED EMBODIMENTS

The benefits of the present invention become evident in the following detailed description of the present invention. This invention is suitable for producing a variety of films, including but not limited to diamond and diamond-like films, Silicon Oxide and Silicone Oxide doped films, and SiOₓN_{y} films.

The most significant aspect of the present invention is a novel plasma reactor for CVD capable of creating a spiral flow of precursor gas over a substrate prior to plasma formation and during plasma enhanced deposition. This spiral flow is accomplished by a configuration of means for inputting precursor gas at controllable input rates used in conjunction with a means for exhausting precursor gas at controllable exhaust rates from a plasma deposition chamber. A plasma initiated in this flow by any known means is particularly stable, in that the operator can control the power density or deposition rate of the plasma as it extends along the surface of a substrate from the substrate's central axis. This is a significant improvement over known plasma deposition processes, in that plasmas created in these known processes decrease in intensity from a substrate's central point and thus are unable to consistently deposit a thin film over large substrates. Also, this homogeneous distribution of gas over the substrate results in a plasma capable of depositing thin films at a higher deposition rate than is possible with the prior art.

The input and exhaust means are used in a plasma deposition chamber cavity. The present invention is not limited to deposition in a cavity of any particular size or shape. The input means are located proximate to the substrate surface, both surrounding the surface and close to the surface boundary. The input means are movable, so as to modify the position of the gas flow relative to the surface to achieve various deposition thicknesses or deposition shapes. In a preferred embodiment, the input means is in the form of one or more discreet apertures, located around the boundary of the surface. The input means is configured so that the path of the gas introduced through the input means includes a tangential flow component relative to the edge of the substrate (or the edge of the desired deposition area). A “tangential flow component” is defined as a directional component of the gas input means that points in a direction so that both the directional component and the edge of the substrate (or deposition area) pass through a single point with the same direction, and is in a plane at least substantially parallel to the plane of the substrate surface. The object of this feature is to input gas having an initial path following the periphery of the substrate/deposition area. For circular substrates, inputted gas initially follows the periphery of the substrate (and is thus circular), and the path is modified into a spiral flow by the force applied to the gas by the exhaust means. In another embodiment, the input means is in the form of a hollow ring jet, described more particularly in the example below.

The exhaust means may consist of apertures through which precursor gas will exit the deposition cavity, which are positioned at a preselected distance above the substrate surface. In a preferred embodiment, the exhaust means consist of one central exhaust aperture and a preselected number of peripheral exhaust apertures located near to and around the central exhaust aperture. This embodiment is more particularly described in the example below. The exhaust means are also movable relative to the substrate surface, so as to effect the shape of the gas flow to achieve different deposition sizes or shapes.

The central exhaust aperture is connected to a means for varying the exhaust rate of gas through the central exhaust aperture. The rate of exhaust through the peripheral exhaust apertures can be varied independently from the exhaustion rate through the central exhaust aperture. This ability to independently vary the exhaust rate through the central and peripheral apertures allows the operator to both create and modify the spiral flow of precursor gas both before and during plasma deposition.

An additional embodiment consists of a preselected number of containment apertures located around and near the substrate surface. The containment apertures are positioned at a greater distance from the surface than the input means. Additional precursor gas introduced through the containment apertures before the plasma is struck can be used during deposition to aid in maintaining the spiral or cylindrical shape of the gas flow and to restrict the gas flow to an area above the substrate surface.

To fully illustrate and describe the present invention, the present invention is shown in the context of an example. This embodiment, similar to one described in German Patent DE 19802971A1, is merely illustrative, and is not meant to limit the availability of the invention for use in other embodiments and configurations.

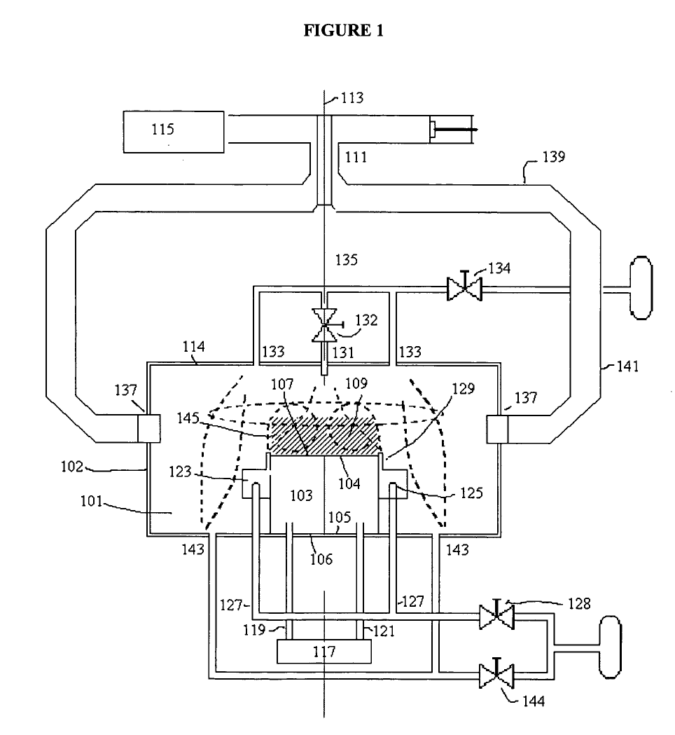

An example of a potential use of the present invention is seen in FIG. 1, and consists of cylindrical cavity 101, located inside cylindrical chamber 102 and containing cylindrical substrate platform 103. Substrate platform 103 consists of substrate bearing surface 104 and base 105, and rests in chamber 102 so that base 105 is in contact with inner floor 106 of chamber 102. Substrate 107 is placed on substrate bearing surface 104, above which surface plasma 109 is created. Axis 113 intersects a plane containing substrate bearing surface 104 in the center of the surface and is perpendicular to both the plane and to interior wall 114. Microwave energy enters cavity 101 via coaxial line 111 and through dielectric window 137 from a microwave produced by generator 115. This configuration offers advantages such as a larger dielectric window area and a larger chamber volume, which aid in reducing plasma deposition on the window. Substrate platform 103 is connected to cooling device 117 by pipes 119 and 121, which travel in a direction parallel to axis 113. Precursor gas enters into cylindrical (or ring) enclosure 123 through input apertures 125, which are connected to an external source of gas through pipe 127. The input rate of the gas through pipe 127 can be adjusted with input valve 128. Gas enters cavity 101 from enclosure 123 through ring jet 129.

Precursor gas exits cavity 101 via central exhaust aperture 131 and peripheral exhaust apertures 133. peripheral exhaust apertures 133 are connected to central exhaust aperture 131 through manifold 135. The exhaustion rate of apertures 131 and 133 can be simultaneously adjusted by adjusting peripheral exhaust valve 134. The exhaustion rate through central exhaust aperture 131 can be further adjusted relative to peripheral exhaust apertures 133 by using central exhaust valve 132.

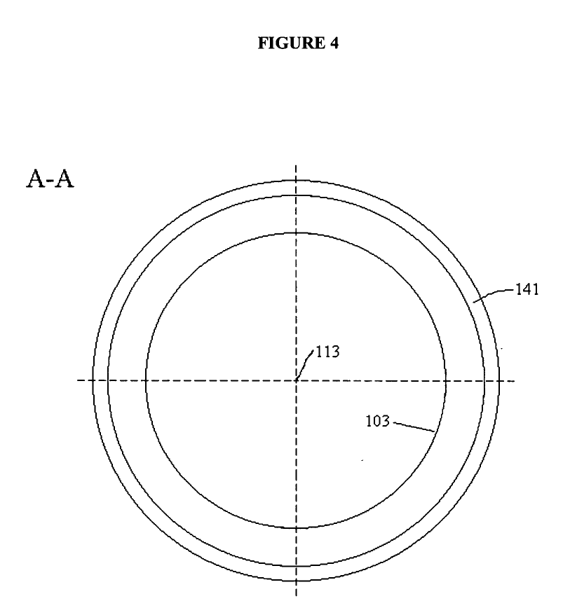

Dielectric ring window 137 surrounds chamber 103 and is hermetically sealed to chamber 103 by a material that does not absorb microwaves. Window 137 is connected to coaxial line 111 through radial line 139 and coaxial line 141, ensuring axially symmetric input of an electromagnetic wave through window 137, as shown in FIG. 4.

Containment apertures 143, connected with a source of precursor gas, are located at the bottom of cavity 101 and on inner floor 106, symmetrically to axis 113.

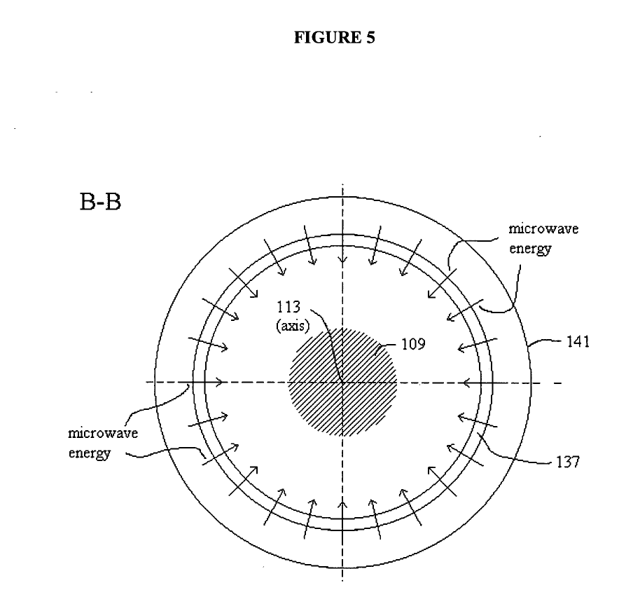

The present device works as follows. The microwave enters cavity 101 through dielectric window 137. A total electromagnetic field over substrate 107 with a maximal intensity value occurs due to axially symmetric input of microwave energy into cavity 101. Introduction of microwaves into cavity 101 is illustrated in FIG. 5.

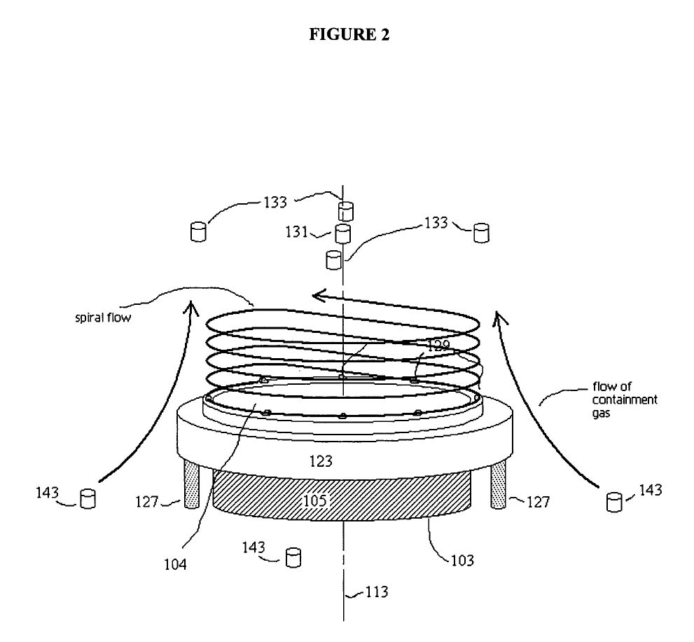

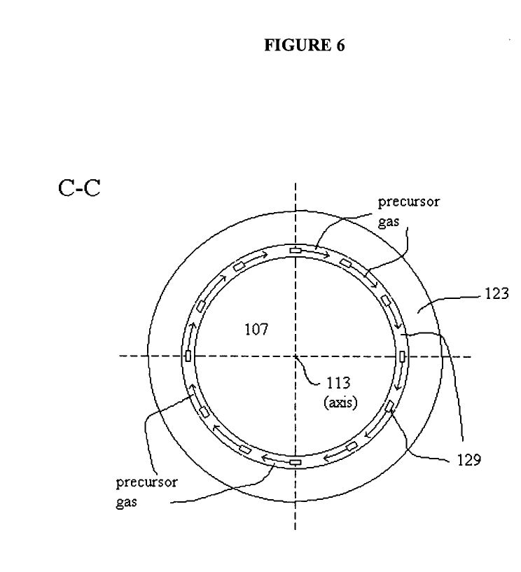

Precursor gas enters the cavity through ring jet 129 as a rotating flow. Jets 125 give rotation to the flow of gas (see FIG. 6). The rotating flow of gas creates central rotary zone 145 above the surface of substrate platform 103. The portion of entered precursor gas that enters zone 145 travels along closed lines created by the rotary flow. The rotary flow is also represented in FIG. 2.

The existence in this zone of closed lines of gas current provides prime conditions for formation and maintenance of a plasma inside this zone. The gas enters zone 145 on the border of the plasma. The rotary flow of gas creates a relatively large, stable, and symmetric plasma, with a diameter approximately equal to that of ring jet 129, that has a uniform distribution of precursor gas over the substrate and can deposit a homogeneous film of constant thickness on the entire area of a substrate.

As a result, conditions exist for the formation of a plasma that can be restricted to an area above the surface of substrate 107. These conditions allow for an increased input of microwave energy, and a resultant increased discharge capacity. The distance between a substrate 107 and the top of chamber 103 can considerably exceed the height of the plasma. This allows the microwave energy to enter the plasma through all of its surface area, and as a result allows an increase in the diameter of a substrate. The plasma is spatially restricted and exists at a relatively large distance from the dielectric window 137. Moving platform 103 of substrate 107 in relation to ring jet 129 and input apertures 125 allows adjustment of the location of central rotary zone 145 in relation to substrate 107, and thus adjustment of the size of a plasma and its influence on substrate 107.

Through containment apertures 143, an additional flow of precursor gas can be introduced to restrict the formation of rotary zone 145 to an area above platform 103, to aid in maintaining the cylindrical shape of the flow of gas above the substrate, and also to adjust lines of a current of the basic flow of precursor gas if necessary. The input of gas through containment apertures 143 can be controlled by adjusting containment valve 144.

The above description is merely a single example of a plasma reactor configuration that could utilize a cylindrically rotating plasma. This plasma could be used in a variety of configurations and power sources, depending on the individual needs of the application. The cylindrically rotating plasma offers the advantage, in many configurations, of a more uniform and spatially restricted deposition

The present invention is further illustrated by the following examples, but is not limited thereby.

### EXAMPLE 1

Diamante film deposition

| Substrate diameter: | 110 mm |
|---|---|
| Pressure: | 75 mbar |
| Rotated gas flow through jet 129: | 6 liters/min |
| Axial gas flow through apertures 143: | 2.5 liter/min |
| Pumped flow through aperture 131: | 10% |
| Pumped flow through apertures 133: | 90% |

### EXAMPLE 2

Diamante film deposition

| Substrate diameter: | 150 mm |
|---|---|
| Pressure: | 60 mbar |
| Rotated gas flow through jet 129: | 8 liters/min |
| Axial gas flow through apertures 143: | 3 liters/min |
| Pumped flow through aperture 131: | 20% |
| Pumped flow through apertures 133: | 80% |

Having described preferred embodiments of the invention with reference to the accompanying drawings, it is to be understood that the invention is not limited to the precise embodiments, and that various changes and modifications may be effected therein by (those) skilled in the art without departing from the scope or spirit of the invention as defined in the appended claims.

1. A device for plasma enhanced chemical vapor deposition of thin films onto large substrates comprising input means and exhaust means which create a spiral flow of precursor gas at/near a surface of a substrate in a deposition chamber cavity prior to plasma formation and maintain a spiral flow plasma during plasma enhanced deposition.

2. The device according to claim 1, wherein said input means is positioned near said substrate and said exhaust means is located at a preselected distance above said substrate.

3. The device according to claim 1, wherein said input means is a hollow ring jet containing a tangential flow component located near said substrate.

4. The device according to claim 3, wherein said tangential flow component is achieved by use of apparatuses selected from the group consisting of fins and directed input nozzles.

5. The device according to claim 1, wherein said input means consists of at least one input aperture located near said substrate.

6. The device according to claim 1, wherein said exhaust means comprises:
a first exhaust means consisting of a central exhaust aperture; and
a second exhaust means consisting of at least two peripheral exhaust apertures located around and near said first exhaust means.

7. The device according to claim 6, wherein said first exhaust means can exhaust precursor gas at a different rate than said second exhaust means, and wherein said exhaustion rate of said first exhaust means and said exhaustion rate of said second exhaust means can be maintained at a preselected ratio.

8. The device according to claim 1, wherein said substrate can be controllably moved during deposition.

9. The device according to claim 6, wherein said first exhaust means and said second exhaust means are connected to a manifold so as to allow coordinated positioning of said first exhaust means and said second exhaust means.

10. The device according to claim 1, further comprising a number of containment apertures located near said substrate to aid in maintaining a plasma in said spiral flow above said substrate but farther away from said substrate than said input means, and wherein said containment apertures input precursor gas at preselected rates of input.

11. A method of plasma enhanced chemical vapor deposition of thin films over large substrates using a device according to claim 1, comprising the steps of:
a. creating a spiral flow of precursor gas prior to plasma formation using input means of a precursor gas and exhaust means of a precursor gas;
b. initiating formation of a plasma; and
c. maintaining said spiral flow of precursor gas during deposition.

12. The method according to claim 11, wherein said step of maintaining said spiral flow of precursor gas during deposition is accomplished by adjusting rate of input of precursor gas through said input means and rate of exhaustion of precursor gas through said exhaust means.

13. The method according to claim 10, further comprising the step of:
employing containment apertures through which flows additional precursor gas, wherein said additional precursor gas flow assists in accomplishing step c.
